(19) United States
(12) Patent Application Publication
(10) Pub. No.: US 2026/0026043 A1
(43) Pub. Date: Jan. 22, 2026

(54) SEMICONDUCTOR DEVICE

(71) Applicant: Samsung Electronics Co., Ltd., Suwon-si (KR)

(72) Inventors: Wooseok Park, Suwon-si (KR); Jehyoung Koo, Suwon-si (KR); Donghyun Seo, Suwon-si (KR)

(21) Appl. No.: 19/010,762

(22) Filed: Jan. 6, 2025

(30) Foreign Application Priority Data
Jul. 17, 2024 (KR) 10-2024-0094573

(51) Int. Cl. H10D 30/67

(52) U.S. Cl. CPC H10D 30/6735; H10D 30/6757

(57) ABSTRACT

A semiconductor device includes a substrate, a dielectric wall structure extending in a first direction on the substrate, active regions extending in the first direction, a gate structure extending in a second direction on the substrate, intersecting the dielectric wall structure, a plurality of channel layers on the active regions and spaced apart from each other in a third direction surrounded by the gate structure, and source/drain regions on at least one side of the gate structure. The dielectric wall structure includes a lower dielectric wall extending in the first direction, and a first upper dielectric wall overlapping the gate structure in the second direction, on the lower dielectric wall. A first upper surface of the lower dielectric wall in contact with the first upper dielectric wall has a first width, and a lower surface of the first upper dielectric wall has a second width less than the first width.

### CROSS-REFERENCE TO RELATED APPLICATION(S)

This application claims benefit of priority to Korean Patent Application No. 10-2024 -0094573 filed on Jul. 17, 2024 in the Korean Intellectual Property Office, the disclosure of which is incorporated herein by reference in its entirety.

### BACKGROUND

The present inventive concept relates to a semiconductor device.

As demand for implementation of high performance, high speed, and/or multifunctionalization of semiconductor devices increases, a degree of integration of semiconductor devices has been increasing. In manufacturing of semiconductor devices having a fine pattern corresponding to the trend for a high degree of integration of semiconductor devices, it may necessary to implement patterns having a fine width or a fine separation distance. In order to overcome a limitation of operating properties due to a reduction in size of a planar metal oxide semiconductor FET (MOSFET), semiconductor devices having a three-dimensional channel, have been developed.

### SUMMARY

An aspect of the present inventive concept provides a semiconductor device having an improved degree of integration and improved reliability.

According to an aspect of the present inventive concept, there is provided a semiconductor device including a substrate, a dielectric wall structure extending in a first direction on the substrate, active regions extending in the first direction on sides of the dielectric wall structure, a gate structure extending in a second direction perpendicular to the first direction on the substrate, intersecting the dielectric wall structure, a plurality of channel layers on the active regions and spaced apart from each other in a third direction perpendicular to the first direction and the second direction, the plurality of channel layers surrounded by the gate structure, and source/drain regions on at least one side of the gate structure, on the sides of the dielectric wall structure, the source/drain regions electrically connected to the plurality of channel layers. The dielectric wall structure may comprise a lower dielectric wall extending in the first direction, and a first upper dielectric wall on the lower dielectric wall overlapped by the gate structure in the second direction. A first upper surface of the lower dielectric wall may have a first width, and a lower surface of the first upper dielectric wall may have a second width less than the first width.

According to another aspect of the present inventive concept, there is provided a semiconductor device including a substrate, a dielectric wall structure extending in a first direction on the substrate, a gate structure extending in a second direction perpendicular to the first direction on the substrate, intersecting the dielectric wall structure, the gate structure including gate electrodes separated from each other by the dielectric wall structure, and a plurality of channel layers spaced apart from each other in a third direction perpendicular to the first direction and the second direction, the plurality of channel layers on sides of the dielectric wall structure, and the plurality of channel layers respectively at least partially surrounded by the gate electrodes. In a region in which the dielectric wall structure overlaps the gate electrodes in the second direction, a side surface of the dielectric wall structure may have a step structure.

According to another aspect of the present inventive concept, there is provided a semiconductor device including a substrate including an active region extending in a first direction, a gate structure extending in a second direction perpendicular to the first direction on the substrate, intersecting the active region, a dielectric wall structure extending in the first direction, the dielectric wall structure extending into the gate structure, source/drain regions in regions in which the active region is recessed, on sides of the gate structure, and a contact plug partially recessed into an upper surface of the source/drain region, the contact plug electrically connected to the source/drain region. The dielectric wall structure may include a first upper dielectric wall overlapping the gate structure in the second direction, a second upper dielectric wall including a region overlapping the source/drain region in the second direction, and a lower dielectric wall extending in the first direction below the first upper dielectric wall and the second upper dielectric wall. The first upper dielectric wall may include a material having a dielectric constant, lower than that of the lower dielectric wall.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a schematic perspective view of a semiconductor device according to example embodiments;

FIG. 2 is a schematic plan view of a semiconductor device according to example embodiments;

FIGS. 3A, 3B, 3C, and 3D are schematic cross-sectional views of a semiconductor device according to example embodiments;

FIGS. 4 and 5 are schematic partially enlarged views of a semiconductor device according to example embodiments;

FIGS. 6, 7, 8, 9, 10, 11, and 12 are schematic partially enlarged views of a semiconductor device according to example embodiments;

FIGS. 13 and 14 are schematic partially enlarged views of a semiconductor device according to example embodiments;

FIG. 15 is a schematic cross-sectional view of a semiconductor device according to example embodiments;

FIGS. 16A, 17A, 18, 19A, 20, 21A, 22A, 23, 24A, 25A, 26A, 27A, and 28A are diagrams of sequential processes in a method of manufacturing a semiconductor device according to embodiments of the present inventive concept; and

FIGS. 16B, 17B, 19B, 21B, 22B, 24B, 25B, 26B, 27B, and 28B are diagrams of sequential processes in a method of manufacturing a semiconductor device according to embodiments of the present inventive concept.

### DETAILED DESCRIPTION

Hereinafter, preferred example embodiments of the present inventive concept will be described with reference to the accompanying drawings. Hereinafter, terms such as “top,” “upper portion,” “upper surface,” “above,” “bottom,” “lower portion,” “lower surface,” “below,” and “side surface” may be denoted by reference numerals and refer to the drawings, except where otherwise indicated.

The terms “first,” “second,” etc., may be used herein merely to distinguish one component, layer, direction, etc. from another. The terms “comprises,” “comprising,” “includes” and/or “including,” when used herein, specify the presence of stated elements, but do not preclude the presence of additional elements. The term “and/or” includes any and all combinations of one or more of the associated listed items. The term “connected” may be used herein to refer to a physical and/or electrical connection. When components or layers are referred to herein as “directly” on, or “in direct contact” or “directly connected,” no intervening components or layers are present. Likewise, when components are “immediately” adjacent to one another, no intervening components may be present.

Components or layers described with reference to “overlap” in a particular direction may be at least partially obstructed by one another when viewed along a line extending in the particular direction or in a plane perpendicular to the particular direction. The term “surrounding” or “covering” or “filling” as may be used herein may not require completely surrounding or covering or filling the described elements or layers, but may, for example, refer to partially surrounding or covering or filling the described elements or layers, for example, with voids or other discontinuities throughout.

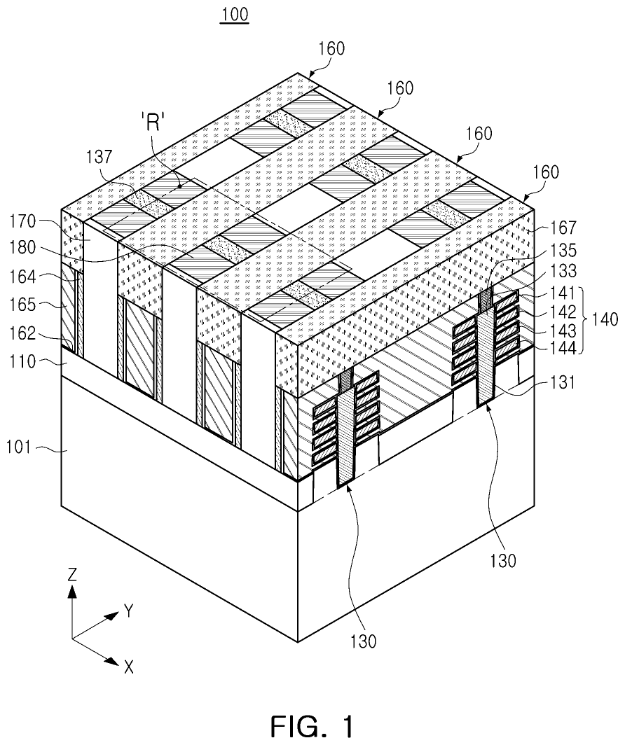

FIG. 1 is a schematic perspective view of a semiconductor device according to example embodiments.

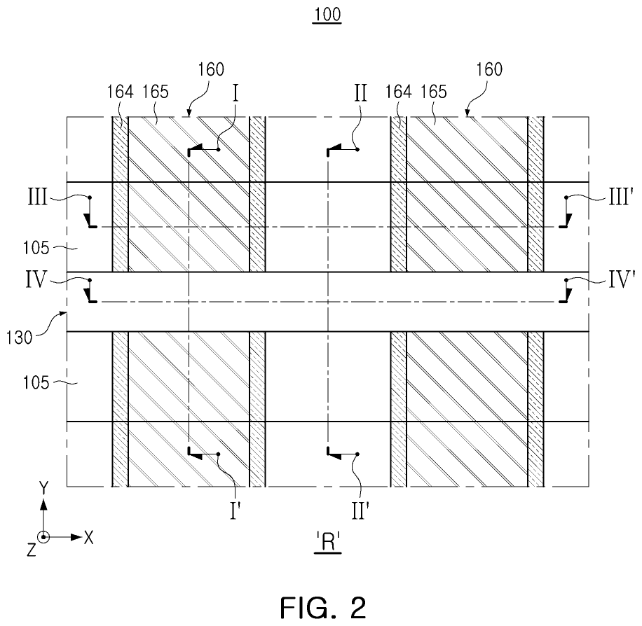

FIG. 2 is a schematic plan view of a semiconductor device according to example embodiments. FIG. 2 is a plan view of region “R” of the semiconductor device of FIG. 1. For case of description, FIG. 1 illustrates only some components of the semiconductor device.

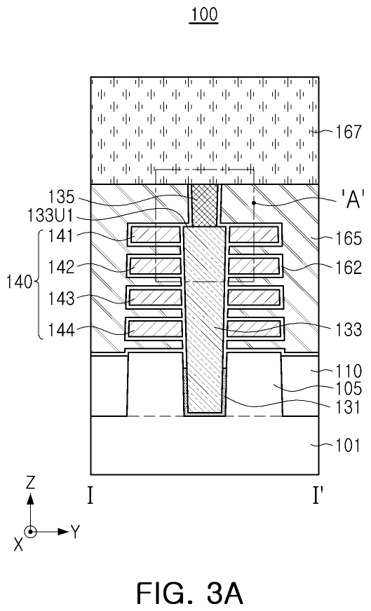

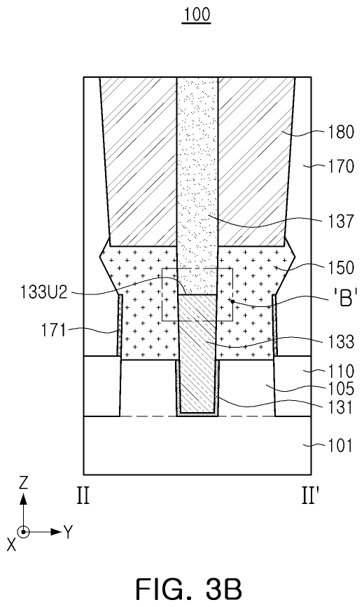

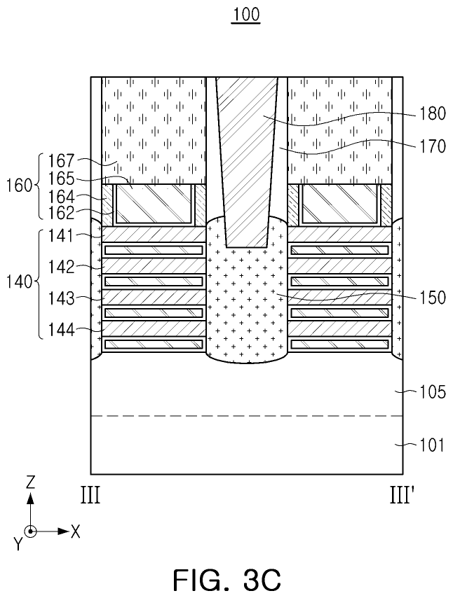

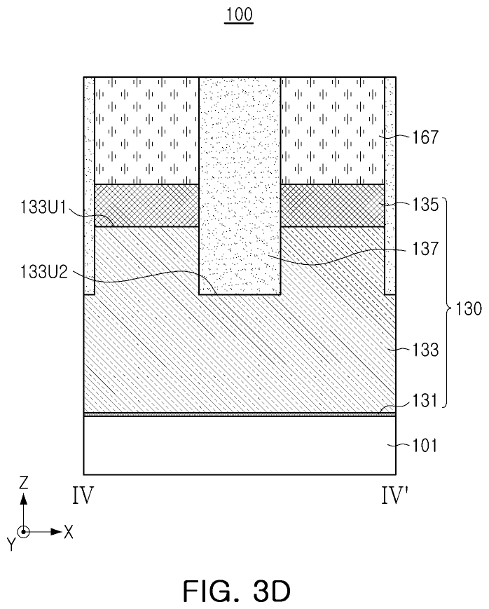

FIGS. 3A, 3B, 3C, and 3D are schematic cross-sectional views of a semiconductor device according to example embodiments. FIG. 3A is a cross-sectional view of the semiconductor device of FIG. 2, taken along line I-I′. FIG. 3B is a cross-sectional view of the semiconductor device of FIG. 2, taken along line II-II′. FIG. 3C is a cross-sectional view of the semiconductor device of FIG. 2, taken along line III-III′. FIG. 3D is a cross-sectional view of the semiconductor device of FIG. 2, taken along line IV-IV′.

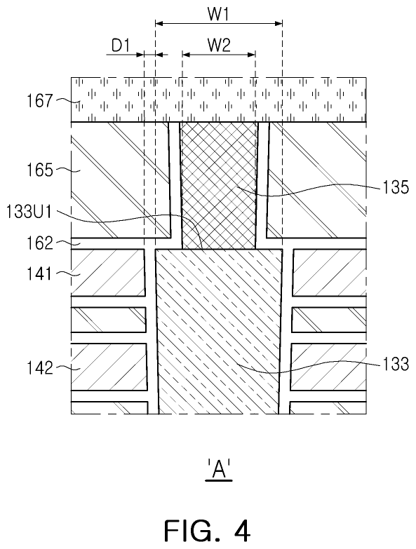

FIG. 4 is a schematic partially enlarged view of a semiconductor device according to example embodiments. FIG. 4 is an enlarged view of region “A” of FIG. 3A.

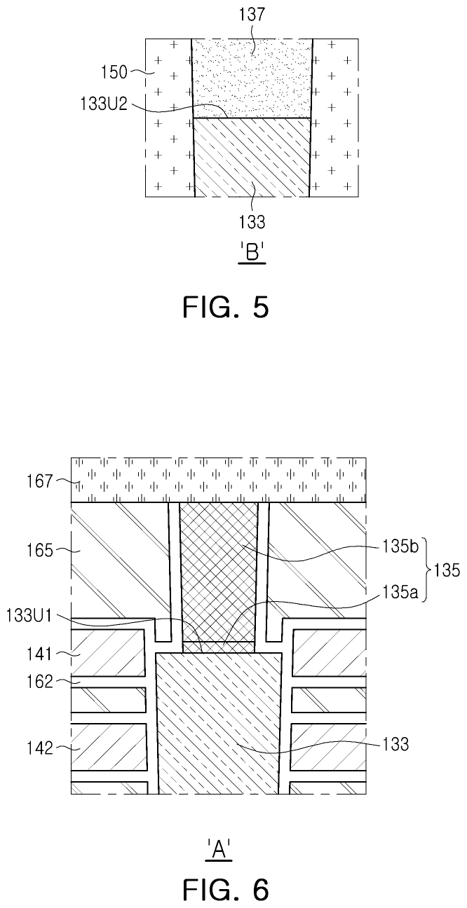

FIG. 5 is a schematic partially enlarged view of a semiconductor device according to example embodiments. FIG. 5 is an enlarged view of region “B” of FIG. 3B.

Referring to FIGS. 1, 2, 3A, 3B, 3C, 3D, 4, and 5, a semiconductor device 100 may include a substrate 101 including active regions 105, a dielectric wall structure 130 disposed between adjacent active regions 105, channel structures 140 including first, second, third, and fourth channel layers 141, 142, 143, and 144 disposed on the active regions 105 to be vertically spaced apart from each other, gate structures 160 extending to intersect the active region 105, the gate structures 160 respectively including a gate electrode 165, source/drain regions 150 in contact with the channel structures 140, and contact plugs 180 electrically connected to the source/drain regions 150. The semiconductor device 100 may further include an isolation layer 110 and an interlayer insulating layer 170.

In the semiconductor device 100, the active region 105 may have a fin structure, and the gate electrode 165 may be disposed between the active region 105 and the channel structure 140, between the first, second, third, and fourth channel layers 141, 142, 143, and 144 of the channel structure 140, and on the channel structure 140. Accordingly, the semiconductor device 100 may include a transistor having a multi-bridge channel FET (MBCFET™) structure, a gate-all-around type field effect transistor.

The substrate 101 may have an upper surface extending in an X-direction and a Y-direction. The substrate 101 may include a semiconductor material, for example, a group IV semiconductor, a group III-V compound semiconductor, or a group II-VI compound semiconductor. For example, the group IV semiconductor may include silicon, germanium, or silicon-germanium. The substrate 101 may be provided as a bulk wafer, an epitaxial layer, a silicon on insulator (SOI) layer, or a semiconductor on insulator (SeOI) layer. In example embodiments, the substrate 101 and the active region 105 may be an insulating layer formed integrally with the isolation layer 110. In this case, the insulating layer may be a layer formed by removing and/or oxidizing the substrate 101 and the active region 105 formed of a semiconductor material during a manufacturing process. In example embodiments, the substrate 101 may include oxide, nitride, or a combination thereof.

The substrate 101 may include the active region 105 disposed on an upper portion thereof. The active region 105 is defined by the isolation layer 110 in the substrate 101, and may be disposed to extend in a first direction, for example, the X-direction. However, depending on a description method, the active region 105 may be described as a separate component from the substrate 101. The active region 105 may partially protrude onto the isolation layer 110, and an upper surface of the active region 105 may be positioned on a level, higher than that of an upper surface of the isolation layer 110. The active region 105 may be formed as a portion of the substrate 101, or may include an epitaxial layer grown from the substrate 101. However, on both sides of the gate structure 160, the active region 105 may be partially recessed to form recess regions, and the source/drain regions 150 may be disposed in the recess regions.

In example embodiments, the active region 105 may or may not include a well region including impurities. For example, in a P-type transistor (pFET), the well region may include N-type impurities such as phosphorus (P), arsenic (As), or antimony (Sb). In an N-type transistor (nFET), the well region may include P-type impurities such as boron (B), gallium (Ga), or indium (In). For example, the well region may be positioned to have a predetermined depth from the upper surface of the active region 105. In example embodiments, a pair of active regions 105, disposed on both sides of the dielectric wall structure 130, may include the same P-type or N-type impurities. In example embodiments, the pair of active regions 105, disposed on the both sides of the dielectric wall structure 130, may include different conductivity types of impurities.

The isolation layer 110 may define an active region 105 in the substrate 101. The isolation layer 110 may be formed using, for example, a shallow trench isolation (STI) process. The isolation layer 110 may expose the upper surface of the active region 105 and may partially expose an upper portion of the active region 105. In some example embodiments, the isolation layer 110 may have a curved upper surface having a higher level as a distance to the active regions 105 gradually decreases. The isolation layer 110 may be formed of an insulating material. The isolation layer 110 may include, for example, oxide, nitride, or a combination thereof.

The dielectric wall structure 130 may extend on the substrate 101 in the first direction, for example, the X-direction. The dielectric wall structure 130 may extend in the first direction between adjacent active regions 105. The dielectric wall structure 130 may pass through the gate structure 160 to separate the gate electrodes 165 from each other, and may allow the source/drain regions 150, disposed on both sides thereof, to be spaced apart from each other. A lowermost surface of the dielectric wall structure 130 may be in contact with an upper surface of the substrate 101. An uppermost surface of the dielectric wall structure 130 may be coplanar with an upper surface of a gate capping layer 167. The dielectric wall structure 130 may have a side surface having a step at a boundary between a lower dielectric wall 133 and a first upper dielectric wall 135. The step may be positioned on a level, lower than that of an upper surface of the gate electrode 165. On a level lower than that of the step, a side surface of the dielectric wall structure 130 may be inclined toward the substrate 101 such that a width thereof decreases. The dielectric wall structure 130 may include a lower cladding film 131, the lower dielectric wall 133, the first upper dielectric wall 135, and a second upper dielectric wall 137.

The lower cladding film 131 may extend in the first direction between the lower dielectric wall 133 and the active region 105 and between the lower dielectric wall 133 and the substrate 101. An upper end of the lower cladding film 131 may be positioned on a level, the same as or lower than that of the upper surface of the isolation layer 110. The lower cladding film 131 may be in contact with the substrate 101, the active region 105, and the source/drain regions 150. The lower cladding film 131 may be in contact with a lower surface of the source/drain region 150. The lower cladding film 131 may include an insulating material. In example embodiments, a thickness of the lower cladding film 131 may be substantially equal to or less than a thickness of a gate dielectric layer 162. In example embodiments, the lower cladding film 131 may include a material different from that of the lower dielectric wall 133. In example embodiments, the lower cladding film 131 may include oxide, nitride, or a combination thereof. In example embodiments, the lower cladding film 131 may include silicon oxide. For example, the lower cladding film 131 may include SiO. In example embodiments, the lower cladding film 131 may be omitted.

The lower dielectric wall 133 may extend on the substrate 101 in the first direction. The lower dielectric wall 133 may be spaced apart from the substrate 101, the active region 105, and the gate electrode 165 by the lower cladding film 131 and the gate dielectric layer 162. In example embodiments, the lower dielectric wall 133 may have a side surface inclined toward the substrate 101 such that a width thereof decreases. The lower dielectric wall 133 may have a first upper surface 133Ul and a second upper surface 133U2. The first upper surface 133U1 may be an upper surface of a portion of the lower dielectric wall 133 overlapping the gate electrode 165 in a second direction and may be in contact with the first upper dielectric wall 135. The second upper surface 133U2 may be an upper surface of a portion of the lower dielectric wall 133 overlapping the source/drain region 150 in the second direction and may be in contact with the second upper dielectric wall 137. The first upper surface 133U1 may be positioned on a level higher than that of the second upper surface 133U2. The first upper surface 133U1 may be positioned on a level lower than that of the upper surface of the gate electrode 165. In example embodiments, the first upper surface 133U1 may be positioned on a level substantially the same as that of an upper surface of the first channel layer 141, an uppermost channel layer. The first upper surface 133U1 may have a first width W1. The first width W1 may refer to a width in the second direction, for example, in the Y-direction. The second upper surface 133U2 may be positioned on a level, lower than that of a lower surface of the contact plug 180. The lower dielectric wall 133 may include an insulating material. In example embodiments, the lower dielectric wall 133 may include a material different from that of the lower cladding film 131. For example, the lower cladding film 131 may include oxide, and the lower dielectric wall 133 may include nitride. In example embodiments, oxide, nitride, or a combination thereof may be included. In example embodiments, a first distance D1 between the first upper surface 133U1 and the first channel layer 141 in a horizontal direction, for example, in the second direction, may be 1 to 5 nm.

The first upper dielectric wall 135 may be disposed on the first upper surface 133U1 of the lower dielectric wall 133 and may overlap the gate electrode 165 in the second direction. In example embodiments, the first upper dielectric wall 135 may entirely overlap the gate electrode 165 in the second direction. The first upper surface 133U1 of the lower dielectric wall 133 may have a first width W1, and a lower surface of the first upper dielectric wall 135 may have a second width W2 less than the first width W1. In example embodiments, the first upper dielectric wall 135 may have a side surface inclined toward the substrate 101 such that a width thereof decreases, but the present inventive concept is not limited thereto. In example embodiments, surfaces of the first upper dielectric wall 135 may be irregular, uneven surfaces. In the same manner as the first width W1, the second width W2 may refer to a width in the second direction, for example, in the Y-direction. Although FIG. 4 illustrates that the first width WI of the lower dielectric wall 133 is greater than the second width W2 of first upper dielectric wall 135, embodiments are not limited thereto and the second width W2 may be greater than the first width W1. In example embodiments, the first width WI may be 10 nm to 25 nm, and the second width W2 may be 5 nm to 15 nm. The first upper dielectric wall 135 may separate the gate electrodes 165 from each other. An upper surface of the first upper dielectric wall 135 may be positioned on a level the same as or higher than the upper surface of the gate electrode 165. The first upper dielectric wall 135 may include an insulating material. In example embodiments, the first upper dielectric wall 135 may include a material different from that of the lower dielectric wall 133. In example embodiments, the first upper dielectric wall 135 may include a material same as that of gate spacer layers 164. In example embodiments, the first upper dielectric wall 135 may include a material having a dielectric constant, lower than that of the lower dielectric wall 133. In example embodiments, the dielectric constant of the material, included in the first upper dielectric wall 135, may have a value of 3 to 10. In example embodiments, the first upper dielectric wall 135 may include oxide, nitride, or a combination thereof. In example embodiments, the first upper dielectric wall 135 may be formed of a low-K film, and may include, for example, at least one of SiO, SiN, SiCN, SiOC, SION, SiOCN, or combinations thereof.

The second upper dielectric wall 137 may be disposed on the second upper surface 133U2 of the lower dielectric wall 133 and may overlap the source/drain region 150 in the second direction. A portion of the second upper dielectric wall 137 may overlap the source/drain region 150 in the second direction, and the other portion of the second upper dielectric wall 137 may not overlap the source/drain region 150 in the second direction. That is, the second upper dielectric wall 137 may include a region overlapping the source/drain region 150 in the second direction, and a region not overlapping in the second direction. At least a portion of a lower surface of the second upper dielectric wall 137 may be in contact with the second upper surface 133U2 of the lower dielectric wall 133. The source/drain regions 150 and the contact plug 180 may be disposed on both sides of the second upper dielectric wall 137. In example embodiments, the second upper dielectric wall 137 may have a side surface inclined toward the substrate 101 such that a width thereof decreases. The lower surface of the second upper dielectric wall 137 may be positioned on a level lower than that of the lower surface of the first upper dielectric wall 135. An upper surface of the second upper dielectric wall 137 may be positioned on a level higher than that of the upper surface of the first upper dielectric wall 135. The upper surface of the second upper dielectric wall 137 may form an uppermost surface of the dielectric wall structure 130 and may be coplanar with an upper surface of the gate capping layer 167. In example embodiments, the second upper dielectric wall 137 may include a material the same as that of the lower dielectric wall 133. In example embodiments, the second upper dielectric wall 137 may include a material different from that of the lower dielectric wall 133, for example, a material having a lower dielectric constant. In example embodiments, the second upper dielectric wall 137 may include oxide, nitride, or a combination thereof. In example embodiments, the second upper dielectric wall 137 may be formed of a low-K film, and may include, for example, at least one of SiO, SIN, SiCN, SiOC, SION, SiOCN, or combinations thereof.

The semiconductor device 100, including the dielectric wall structure 130, may include the first upper dielectric wall 135 formed by a process separate from that of the lower dielectric wall 133 to stably separate the gate electrodes 165 from each other without loss of a peripheral component that may occur during the process. In particular, a loss that may occur in the first channel layer 141 of the channel structures 140 may be prevented. In addition, the second upper dielectric wall 137 may be included such that adjacent source/drain regions 150 may be stably separated from each other and formed. Descriptions related thereto will be provided in detail in connection with a manufacturing method described below. Accordingly, a semiconductor device may have improved reliability and an improved degree of integration.

The gate structures 160 may be disposed on the active region 105 and the channel structures 140 to intersect the active region 105 and the channel structures 140 and extend in the second direction, for example, the Y-direction. Functional channel regions of transistors may be formed in the active region 105 and/or the channel structures 140, intersecting the gate electrodes 165 of the gate structures 160. Each of the gate structures 160 may include a gate electrode 165, gate dielectric layers 162 between the gate electrode 165 and the first, second, third, and fourth channel layers 141, 142, 143, and 144, gate spacer layers 164 on side surfaces of the gate electrode 165, and a gate capping layer 167 extending on the gate electrode 165 in the second direction.

The gate dielectric layers 162 may be disposed between the active region 105 and the gate electrode 165, between the channel structure 140 and the gate electrode 165, and between the dielectric wall structure 130 and the gate electrode 165 and may be disposed to cover or overlap at least a portion of surfaces of the gate electrode 165. For example, the gate dielectric layers 162 may be disposed to surround all surfaces of the gate electrode 165 except for an uppermost surface of the gate electrode 165. The gate dielectric layers 162 may extend to a space between the gate electrode 165 and the gate spacer layers 164, but the present inventive concept is not limited thereto. The gate dielectric layers 162 may include oxide, nitride, or a high-K material. The high-K material may refer to a dielectric material having a dielectric constant, higher than that of a silicon oxide film (SiO₂). The high-K material may include, for example, at least one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), and/or praseodymium oxide (Pr₂O₃). In some example embodiments, the gate dielectric layer 162 may be formed of a multilayer film.

The gate electrode 165 may be disposed to extend onto the channel structure 140 while filling a space between the first, second, third, and fourth channel layers 141, 142, 143, and 144, on the active region 105. The gate electrode 165 may be spaced apart from the first, second, third, and fourth channel layers 141, 142, 143, and 144 by the gate dielectric layers 162. The gate electrode 165 may include a conductive material, for example, a metal material such as a metal nitride such as a titanium nitride film (TiN), a tantalum nitride film (TaN), or a tungsten nitride film (WN), and/or a metal material such as aluminum (Al), tungsten (W), and/or molybdenum (Mo), or a semiconductor material such as doped polysilicon. Depending on example embodiments, the gate electrode 165 may be formed of two or more multiple layers. In a region not illustrated, the gate electrodes 165 may be electrically connected to upper contact plugs disposed thereon.

The gate spacer layers 164 may be disposed on both sides of the gate electrode 165, on the channel structure 140. The gate spacer layers 164 may insulate the source/drain regions 150 from the gate electrode 165. The gate spacer layers 164 may have a multilayer structure depending on example embodiments. The gate spacer layers 164 may be formed of at least one of oxide, nitride, and oxynitride, and may be formed of a low-K film. The gate spacer layers 164 may include at least one of, for example, SiO, SIN, SiCN, SiOC, SiON, and/or SiOCN. In example embodiments, the gate spacer layers 164 may include a material the same as that of the first upper dielectric wall 135.

The gate capping layer 167 may extend in the second direction, for example, in the Y-direction, on the gate electrode 165 and the gate spacer layers 164. The gate capping layer 167 may include at least one of oxide, nitride, and oxynitride.

The channel structures 140 may be disposed on the active region 105 in regions in which the active region 105 intersects the gate structures 160. Each of the channel structures 140 may include first, second, third, and fourth channel layers 141, 142, 143, and 144, a plurality of channel layers disposed to be spaced apart from each other in a third direction, parallel to the upper surface of the substrate 101, for example, in a Z-direction. The first, second, third, and fourth channel layers 141, 142, 143, and 144 may be sequentially disposed from above, and the first channel layer 141 may be an uppermost channel layer. The channel structures 140 may be electrically connected to the source/drain regions 150. The channel structures 140 may have a width equal to or similar to that of the gate structures 160 in the X-direction and may have a width equal to or less than that of the active region 105 in the Y-direction. In a cross-section in the Y-direction, a lower channel layer, among the first, second, third, and fourth channel layers 141, 142, 143, and 144, may have a width equal to or greater than that of an upper channel layer, among the first, second, third, and fourth channel layers 141, 142, 143, and 144. In example embodiments, the number and shape of channel layers, forming a single channel structure 140, may be changed in various manners. For example, the single channel structure 140 may include three channel layers, two channel layers, or five or more channel layers.

The channel structures 140 may be formed of a semiconductor material, and may include, for example, at least one of silicon (Si), silicon germanium (SiGe), and/or germanium (Ge). For example, the channel structures 140 may be formed of a material the same as that of the active region 105. In some example embodiments, the channel structures 140 may have an impurity region, positioned in a region adjacent to the source/drain regions 150.

The source/drain regions 150 may be disposed in recess regions formed by partially recessing an upper portion of the active region 105, on both sides of the gate structure 160. The source/drain regions 150 may be disposed on both sides of the dielectric wall structure 130. The recess regions may extend along side surfaces of the channel structures 140 and side surfaces of the gate dielectric layers 162. The source/drain regions 150 may be disposed to cover or overlap side surfaces of each of the first, second, third, and fourth channel layers 141, 142, 143, and 144 of the channel structures 140 in the X-direction. Upper surfaces of the source/drain regions 150 may be positioned on a level, the same as or higher than that of upper surfaces of the first channel layers 141 of the channel structures 140. In example embodiments, the level may be changed in various manners. Side surfaces of the source/drain regions 150 may be curved according to the first, second, third, and fourth channel layers 141, 142, 143, and 144 and the gate structure 160. However, in example embodiments, specific shapes of the side surfaces of the source/drain regions 150 may be changed in various manners.

The source/drain regions 150 may include at least one of a semiconductor material, for example, silicon (Si), and/or germanium (Ge), and may further include dopants. For example, when the semiconductor device 100 is a pFET, the dopants may be at least one of boron (B), gallium (Ga), and indium (In). The source/drain regions 150 may include a plurality of epitaxial layers. In example embodiments, a pair of source/drain regions 150, disposed on both side surfaces of a single dielectric wall structure 130, may include the same conductivity type of dopants. In example embodiments, the pair of source/drain regions 150, disposed on both side surfaces of the single dielectric wall structure 130, may include different conductivity types of dopants.

The interlayer insulating layer 170 may be disposed on the isolation layer 110 to cover or overlap the source/drain regions 150, the gate structures 160, and the contact plug 180. The interlayer insulating layer 170 may include at least one of oxide, nitride, and oxynitride, and may include, for example, a low-material. Depending on example embodiments, the interlayer insulating layer 170 may include a plurality of insulating layers.

The peripheral insulating layer 171 may cover or overlap a portion of a side surface of the source/drain region 150. In example embodiments, the peripheral insulating layer 171 may include the same material as that of the gate spacer layers 164 and/or the first upper dielectric wall 135. In example embodiments, the peripheral insulating layer 171 may include oxide, nitride, or a combination thereof. In example embodiments, the peripheral insulating layer 171 may be formed of a low-K film, and may include, for example, at least one of SiO, SiN, SiCN, SiOC, SION, SiOCN, or combinations thereof.

The contact plugs 180 may pass through the interlayer insulating layer 170, may be electrically connected to the source/drain regions 150, and may apply an electrical signal to the source/drain regions 150. The contact plugs 180 may extend into the source/drain regions 150 while recessing the source/drain regions 150. The contact plugs 180 may extend below an upper surface of the first channel layer 141 from above, for example. In example embodiments, the contact plugs 180 may extend below a lower surface of the first channel layer 141. The contact plugs 180 may have side surfaces extending alongside surfaces of the second upper dielectric wall 137 of the dielectric wall structure 130.

The semiconductor device 100 may be packaged with the structure of FIGS. 3A to 3D inverted vertically such that the substrate 101 is positioned thereon, but a form in which the semiconductor device 100 is packaged is not limited thereto. The semiconductor device 100 may include the gate electrode 165 and the dielectric wall structure 130 separating the source/drain regions 150 from each other, and thus may have improved reliability and an improved degree of integration.

In the description of the following example embodiments, descriptions overlapping the above descriptions with reference to FIGS. 1 to 5 will be omitted.

FIGS. 6 to 12 are schematic partially enlarged views of a semiconductor device according to example embodiments. FIGS. 6 to 12 are partially enlarged views corresponding to FIG. 4, an enlarged view of region “A” of FIG. 3A. In the descriptions of FIGS. 6 to 12, repeated descriptions will be omitted.

Referring to FIG. 6, unlike the example embodiment of FIG. 4, the first upper dielectric wall 135 may include a plurality of dielectric layers. In example embodiments, the first upper dielectric wall 135 may include a first dielectric layer 135a and a second dielectric layer 135b on the first dielectric layer 135a. The first dielectric layer 135a may form the lower surface of the first upper dielectric wall 135 and may be in contact with the first upper surface 133U1 of the lower dielectric wall 133. In example embodiments, the first dielectric layer 135a may have a side portion and an upper portion being lost during a process after being formed to cover or overlap a side surface and an upper surface of the second dielectric layer 135b, and thus may have only a remaining lower portion. In addition, unlike the example embodiment of FIG. 4, the first upper surface 133U1 of the lower dielectric wall 133 may be positioned on a level, lower than that of the upper surface of the first channel layer 141. The lower surface of the first upper dielectric wall 135 may be positioned on a level, lower than that of the upper surface of the first channel layer 141, and the first dielectric layer 135a may be positioned on a level, lower than that of the upper surface of the first channel layer 141. The first dielectric layer 135a and the second dielectric layer 135b may include the same insulating material or different insulating materials. Referring to FIG. 3C together, the number of insulating layers, included in the gate spacer layers 164, may be equal to or greater than the number of dielectric layers, included in the first upper dielectric wall 135.

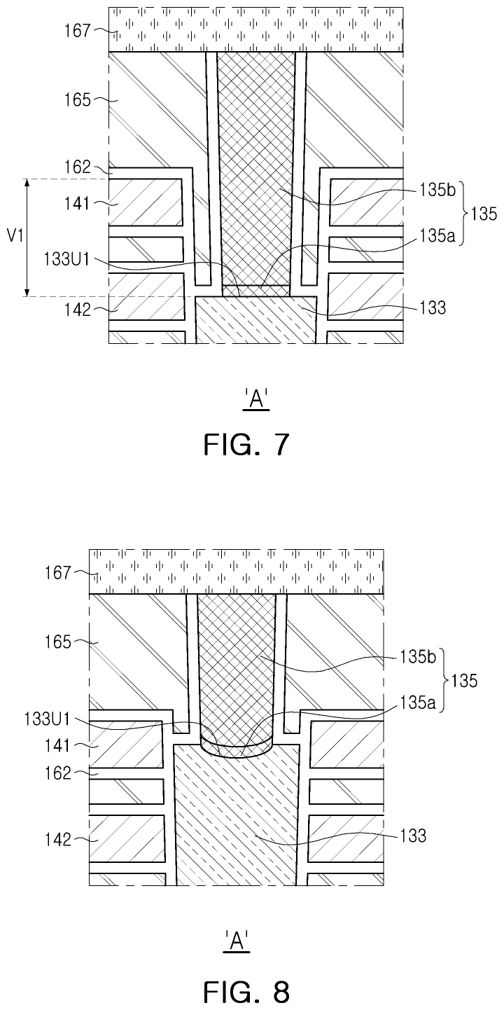

Referring to FIG. 7, unlike the example embodiment of FIG. 6, the first upper surface 133U1 of the lower dielectric wall 133 may be positioned on a level, lower than that of an upper surface of the second channel layer 142. The first upper surface 133U1 of the lower dielectric wall 133 may be positioned on a level, higher than that of an upper surface of the third channel layer 143. A level difference V1 between the first upper surface 133U1 of the lower dielectric wall 133 and the upper surface of the first channel layer 141 may be 0 to 20 nm. The gate electrode 165 may be disposed between the dielectric wall structure 130 and the first channel layer 141 and between the dielectric wall structure 130 and the second channel layer 142.

Referring to FIG. 8, unlike the example embodiment of FIG. 6, the first upper surface 133U1 of the lower dielectric wall 133 may include a portion having a concave shape, and the lower surface of the first upper dielectric wall 135 may have a downwardly convex shape. A lower end of the first upper dielectric wall 135 may be positioned on a level, lower than that of an upper end of the lower dielectric wall 133. In example embodiments, the first upper surface 133U1 may be an irregular, uneven surface.

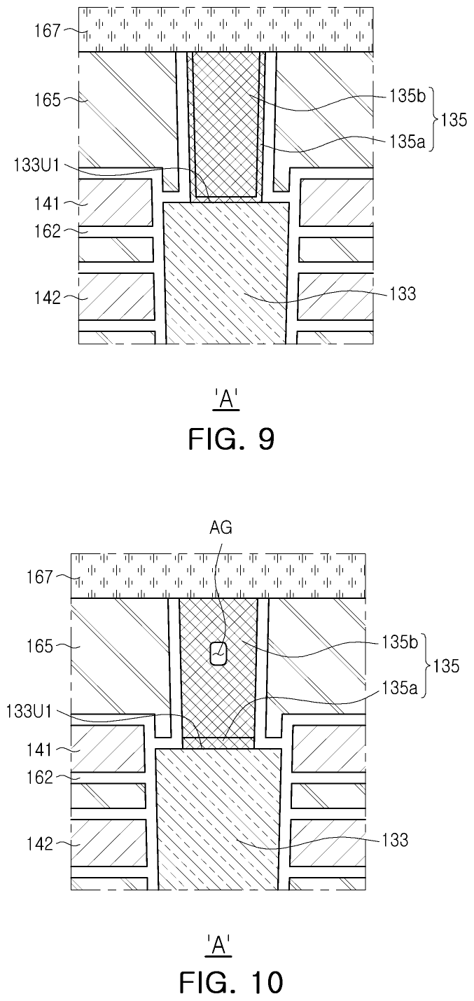

Referring to FIG. 9, unlike the example embodiment of FIG. 6, the first dielectric layer 135a may cover or overlap not only a lower surface of the second dielectric layer 135b but also side surfaces of the second dielectric layer 135b opposing the gate electrode 165. A thickness of the first dielectric layer 135a, covering, overlapping, or on the lower surface of the second dielectric layer 135b, may be equal to or greater than a thickness of the second dielectric layer 135b. In example embodiments, the first dielectric layer 135a may be formed to have a uniform thickness during formation. However, during a subsequent process, the first dielectric layer 135a may be partially lost to have a reduced side surface thickness. In example embodiments, unlike that illustrated, the first dielectric layer 135a may surround the second dielectric layer 135b to cover or overlap at least a portion of the upper surface of the second dielectric layer 135b.

Referring to FIG. 10, an air gap AG may be present in the first upper dielectric wall 135. The air gap AG may refer to an empty space, not filled with a dielectric material. In example embodiments, the air gap AG may be positioned to be closer to the upper surface than the lower surface of the first upper dielectric wall 135. The air gap AG may be spaced apart from the gate dielectric layer 162, the lower dielectric wall 133, and the gate capping layer 167, peripheral components. In example embodiments, a plurality of air gaps AG may be present.

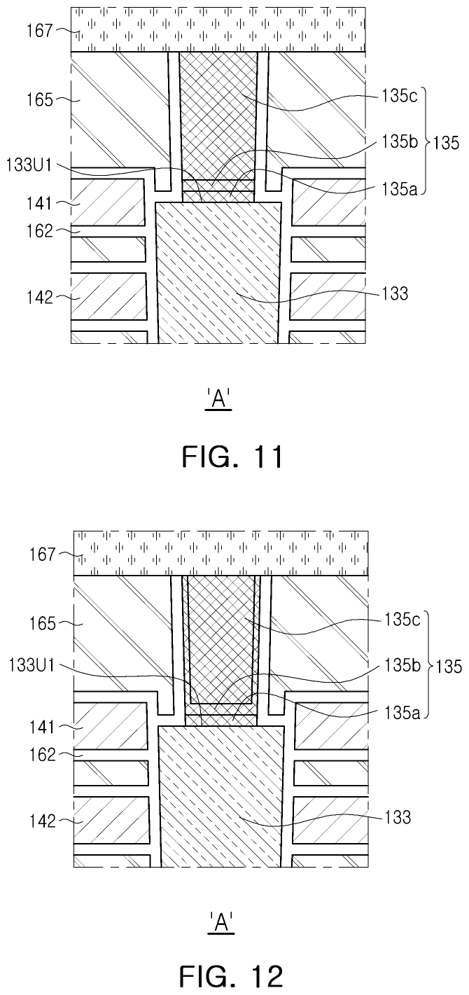

Referring to FIG. 11, unlike the example embodiment of FIG. 6, the first upper dielectric wall 135 may include first, second, and third dielectric layers 135a, 135b, and 135c, sequentially stacked. In example embodiments, the first dielectric layer 135a and the second dielectric layer 135b may be formed to surround the third dielectric layer 135c during initial formation, However, the first dielectric layer 135a and the second dielectric layer 135b may have an upper portion and a side portion being lost depending on a process and may have only a remaining lower portion. The first, second, third dielectric layers 135a, 135b, and 135c may include the same material or different materials. In example embodiments, the first upper dielectric wall 135 may include a larger plurality of dielectric layers.

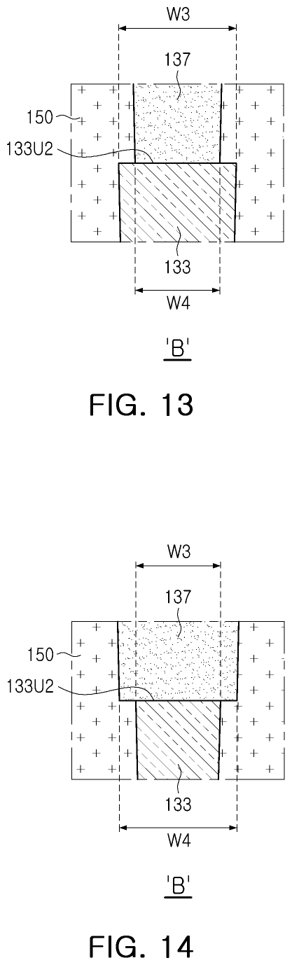

Referring to FIG. 12, unlike the example embodiment of FIG. 11, the first dielectric layer 135a may form a lower portion of the first upper dielectric wall 135, and the second dielectric layer 135b may cover or overlap a lower surface of the third dielectric layer 135c and a side surface of the third dielectric layer 135c opposing the gate electrode 165, on the first dielectric layer 135a. The number and arrangement of a plurality of dielectric layers may be changed in various manners.

FIGS. 13 and 14 are schematic partially enlarged views of a semiconductor device according to example embodiments. FIGS. 13 to 14 are partially enlarged views corresponding to FIG. 5, an enlarged view of region “B” of FIG. 3B.

Referring to FIG. 13, unlike the example embodiment of FIG. 5, a third width W3 of the second upper surface 133U2 of the lower dielectric wall 133 may be greater than a fourth width W4 of the lower surface of the second upper dielectric wall 137. The third width W3 and the fourth width W4 may refer to widths of components in the second direction. The second upper dielectric wall 137 may be formed using a process different from that of the lower dielectric wall 133, such that the third width W3 and the fourth width W4 may be different from each other.

Referring to FIG. 14, unlike the example embodiment of FIG. 13, the third width W3 of the second upper surface 133U2 of the lower dielectric wall 133 may be less than the fourth width W4 of the lower surface of the second upper dielectric wall 137. The third width W3 and the fourth width W4 during initial formation may be different from the third width W3 and the fourth width W4 after process completion.

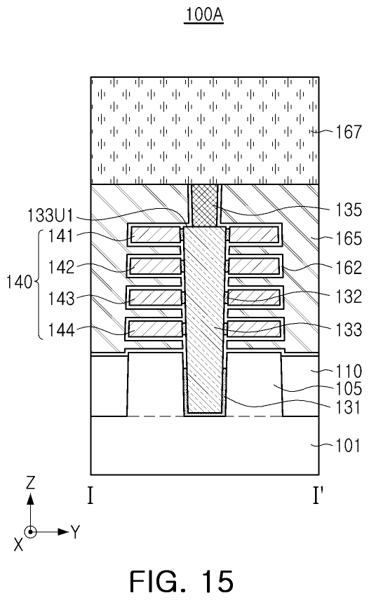

Referring to FIG. 15, unlike the semiconductor device 100 of FIGS. 1 to 5, in a semiconductor device 100A, a dielectric wall structure 130 may further include upper cladding films 132 disposed between a plurality of channel layers 141, 142, 143, and 144 of a lower dielectric wall 133. The upper cladding films 132 may be disposed between the lower dielectric wall 133 and at least one of the plurality of channel layers 141, 142, 143, and 144. The gate dielectric layers 162 may be in contact with upper ends and/or lower ends of the upper cladding films 132, respectively. In example embodiments, the upper cladding films 132 may have a thickness substantially the same as that of the gate dielectric layers 162. The upper cladding films 132 may include a material the same as that of a lower cladding film 131.

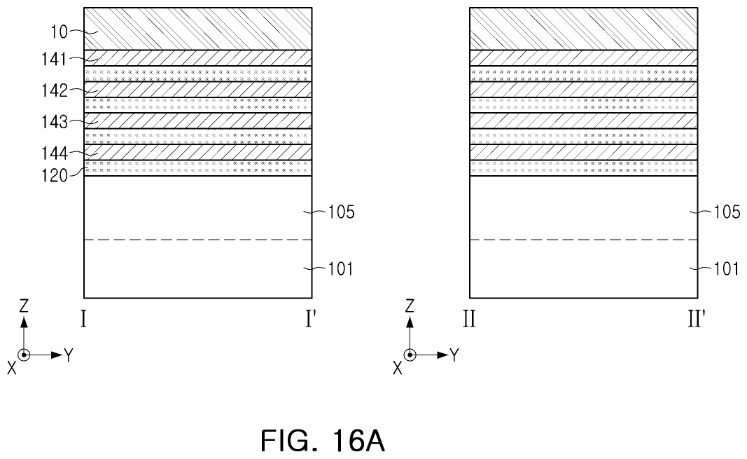

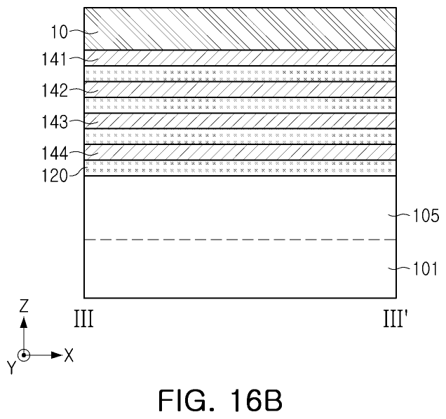

FIGS. 16A, 17A, 18, 19A, 20, 21A, 23A, 24A, 25A, 26A, 27A, and 28A are diagrams of sequential processes in a method of manufacturing a semiconductor device according to embodiments of the present inventive concept. The diagrams may correspond to FIGS. 3A and 3B.

FIGS. 16B, 17B, 19B, 21B, 22B, 24B, 25B, 26B, 27B, and 28B are diagrams of sequential processes in a method of manufacturing a semiconductor device according to embodiments of the present inventive concept. The diagrams may correspond to FIG. 3C.

In the descriptions of FIGS. 16A to 28B, processes may be performed according to a drawing number and the same number of drawings are described as processes performed simultaneously. For example, FIGS. 16A and 16B are described as processes performed simultaneously.

Referring to FIGS. 16A and 16B, sacrificial layers 120 and first, second, third, and fourth channel layers 141, 142, 143, and 144 may be alternately stacked on a substrate 101.

The sacrificial layers 120 may be layers, replaced with gate dielectric layers 162 and gate electrodes 165 below the first channel layer 141 using a subsequent process, as illustrated in FIG. 3A and FIG. 3C. The sacrificial layers 120 may be formed of a material having an etch selectivity with respect to each of the first, second, third, and fourth channel layers 141, 142, 143, and 144. The first, second, third, and fourth channel layers 141, 142, 143, and 144 may include a material different from that of the sacrificial layers 120. For example, the sacrificial layers 120 and the first, second, third, and fourth channel layers 141, 142, 143, and 144 may include a semiconductor material including at least one of silicon (Si), silicon germanium (SiGe), and germanium (Ge), may include different materials, and may include or may not include impurities. For example, the sacrificial layers 120 may include silicon germanium (SiGe), and the first, second, third, and fourth channel layers 141, 142, 143, and 144 may include silicon (Si).

The sacrificial layers 120 and the first, second, third, and fourth channel layers 141, 142, 143, and 144 may be formed by performing an epitaxial growth process from the stack structure. In example embodiments, the number of channel layers, stacked alternately with the sacrificial layers 120, may be changed in various manners.

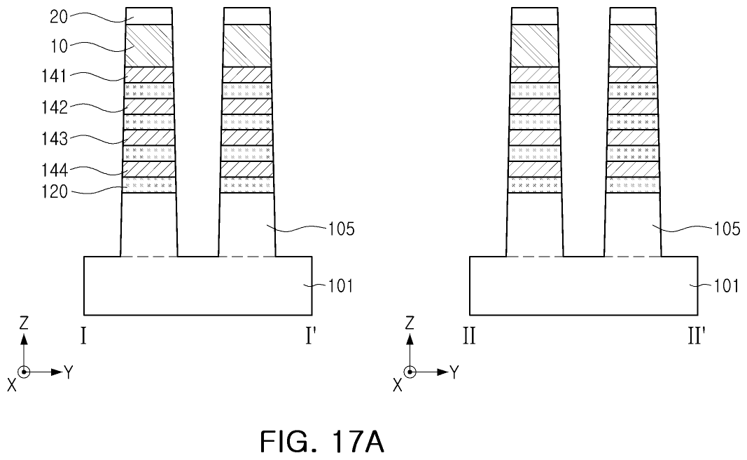

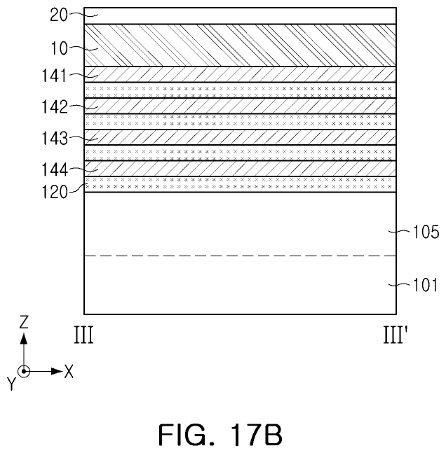

Referring to FIGS. 17A and 17B, the sacrificial layers 120, the first, second, third, and fourth channel layers 141, 142, 143, and 144, and the substrate 101 may be partially removed to form an active structure including an active region 105.

The active structure may be in the form of a line extending in one direction, for example, in an X-direction, after forming etching masks 10 and 20 on an upper surface of an uppermost first channel layer 141. The etching masks 10 and 20 may include a first etching mask 10 and a second etching mask 20. In example embodiments, the first etching mask 10 may include polysilicon, and the second etching mask 20 may include nitride.

The active structure may include the active region 105, the sacrificial layers 120, and the first, second, third, and fourth channel layers 141, 142, 143, and 144. The active structure may be formed in the form of a line extending in a direction, for example, the X-direction, and may be formed to be spaced apart from an active structure adjacent thereto in a Y-direction. Side surfaces of the active structure in the Y-direction may be coplanar with each other, and may be positioned on a straight line.

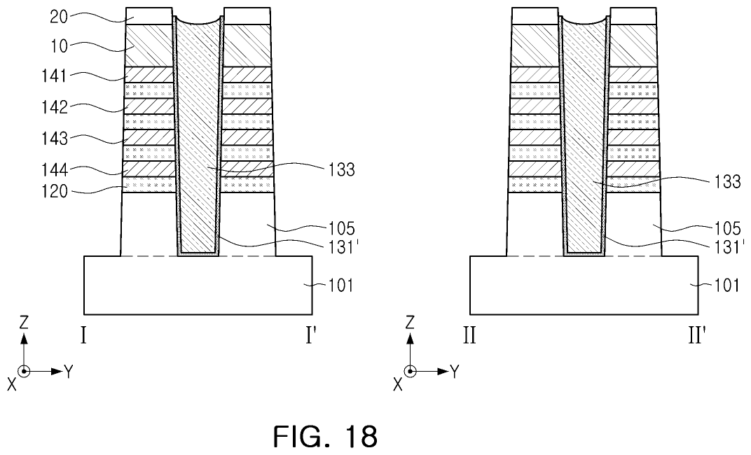

Referring to FIG. 18, a cladding film 131′ and a lower dielectric wall 133 may be formed between adjacent active structures.

The cladding film 131′ and the lower dielectric wall 133 may be formed by sequentially depositing an insulating material on the substrate 101 and the active structure, and then removing a portion of the insulating material except for a portion of the insulating material between adjacent active structures. In example embodiments, oxide, to be included in the cladding film 131′, may be deposited on the substrate 101 and the active structure, and nitride, to be included in the lower dielectric wall 133, may be deposited to fill between adjacent active structures, and then the deposited nitride and oxide may be partially removed to form the cladding film 131′ and the lower dielectric wall 133. The removal process may be performed using dry etching or wet etching. The cladding film 131′ may conformally cover or overlap side surfaces of the first, second, third, and fourth channel layers 141, 142, 143, and 144, side surfaces of the sacrificial layers 120, and an upper surface of the substrate 101, between adjacent active structures, and the lower dielectric wall 133 may fill a space between adjacent active structures, on the cladding film 131′. The cladding film 131′ and the lower dielectric wall 133 may be formed to extend in a first direction, for example, in the X-direction, between adjacent active structures. An upper end of the cladding film 131′ and an upper end of the lower dielectric wall 133 may be positioned on a level, the same as or higher than an upper surface of the first etching mask 10. In example embodiments, a process of generating the cladding film 131′ may be omitted. In this case, a semiconductor device in which the lower cladding film 131 is omitted may be manufactured.

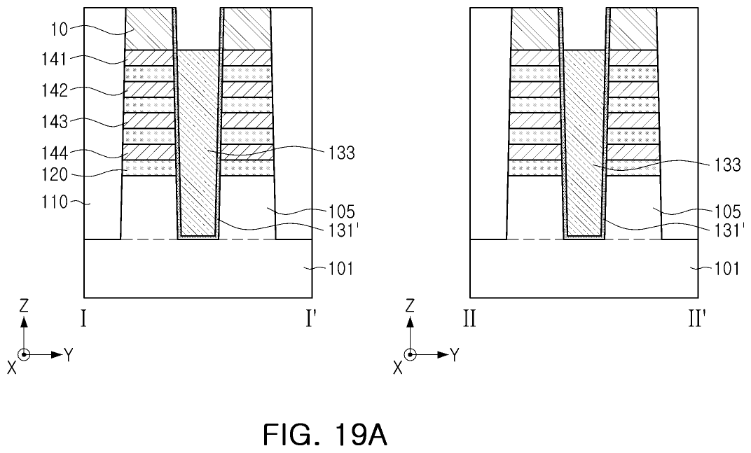

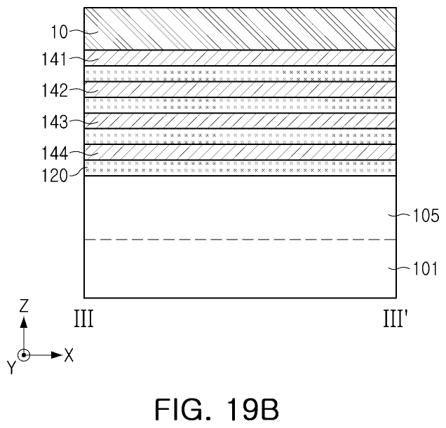

Referring to FIGS. 19A and 19B, an isolation layer 110 may be formed, the second etching mask 20 may be removed, and the lower dielectric wall 133 may be partially removed from an upper surface thereof.

The isolation layer 110 may be formed by filling an insulating material up to a level higher than that of the second etching mask 20 of FIG. 18, and then removing a portion of the insulating material having a level, higher than that of the upper surface of the first etching mask 10. In the present operation, the second etching mask 20 may be removed together. In this case, a portion of the upper surface of the first etching mask 10 may be removed together. In example embodiments, the removal of a portion of the insulating material and the second etching mask 20 may be performed using chemical mechanical polishing (CMP). In example embodiments, the lower dielectric wall 133 may be partially removed such that the upper surface thereof is positioned on a level, substantially the same as that of an upper surface of the first channel layer 141. In example embodiments, the upper surface of the lower dielectric wall 133 may be partially removed to be positioned on a level, lower than the upper surface of the first channel layer 141. According to a depth at which the lower dielectric wall 133 is removed from the upper surface thereof, the example embodiments of FIG. 6 or 7 may be manufactured using a subsequent process. A process of partially removing the upper surface of the lower dielectric wall 133 may be performed using wet etching or dry etching.

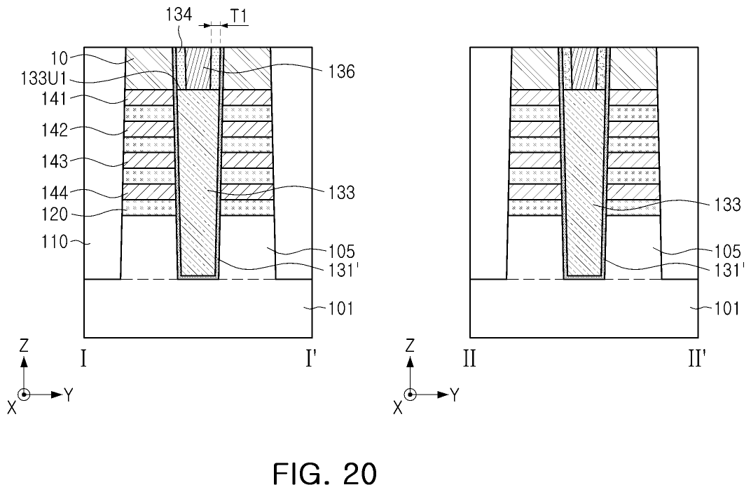

Referring to FIG. 20, a thickness adjustment layer 134 and a sacrificial wall 136 may be formed on the lower dielectric wall 133.

The thickness adjustment layer 134 may be formed by depositing an insulating material to conformally cover or overlap the cladding film 131′, the lower dielectric wall 133, the first etching mask 10, and the isolation layer 110, and then removing a portion of the insulating material except for a portion of the insulating material formed on the cladding film 131′. The thickness adjustment layer 134 may be formed to have a first thickness T1. The first thickness T1 may be adjusted in various manners depending on a width of a first upper dielectric wall 135 to be formed in a subsequent process. As the first thickness T1 increases, a difference between the first width W1 and the second width W2 described with reference to FIG. 4 may increase. In example embodiments, the thickness adjustment layer 134 may include oxide. In example embodiments, a process of forming the thickness adjustment layer 134 may be omitted. In this case, the second width W2 may be formed to be less than the first width WI using a subsequent process. The sacrificial wall 136 may be formed on the lower dielectric wall 133 to fill a space between the thickness adjustment layers 134. For example, the sacrificial wall 136 may include a semiconductor material including at least one of silicon (Si), silicon germanium (SiGe), and/or germanium (Ge), may include different materials, and may include or may not include impurities. The sacrificial wall 136 may have a material composition different from a material composition, included in the sacrificial layers 120 and the first, second, third, and fourth channel layers 141, 142, 143, and 144, to have an etch selectivity with respect to the sacrificial layers 120 and the first, second, third, and fourth channel layers 141, 142, 143, and 144. In example embodiments, the first, second, third, and fourth channel layers 141, 142, 143, and 144 may include silicon (Si), the sacrificial layers 120 may include silicon germanium (SiGe), and the sacrificial wall 136 may include silicon germanium (SiGe) and may have a material composition different from that of silicon germanium (SiGe), included in the sacrificial layers 120. In example embodiments, the sacrificial wall 136 may be formed by depositing silicon germanium (SiGe) conformally covering or overlapping the lower dielectric wall 133, the thickness adjusting layer 134, the first etching mask 10, and the isolation layer 110 and then removing a portion formed on a level, higher than the upper surface of the first etching mask 10 using a method such as CMP or the like. In example embodiments, the sacrificial wall 136 may include a material having a concentration of germanium (Ge), higher than that of the sacrificial layers 120. For example, the sacrificial layers 120 may include germanium (Ge) having an atomic fraction of 15% to 35%, and the sacrificial wall 136 may include germanium (Ge) having an atomic fraction of 35% to 50%.

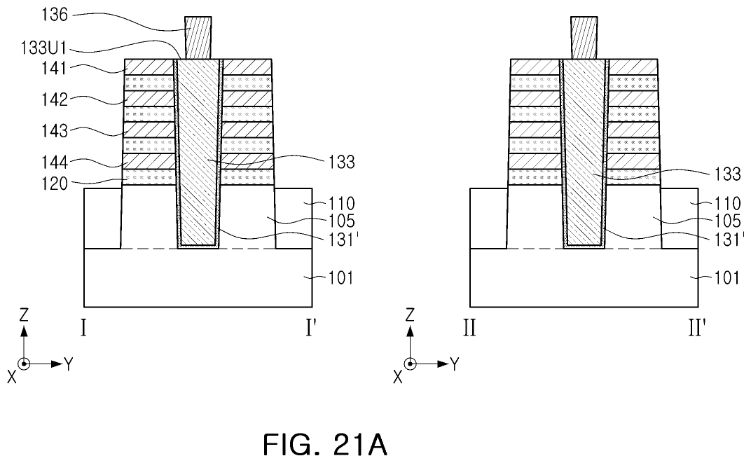

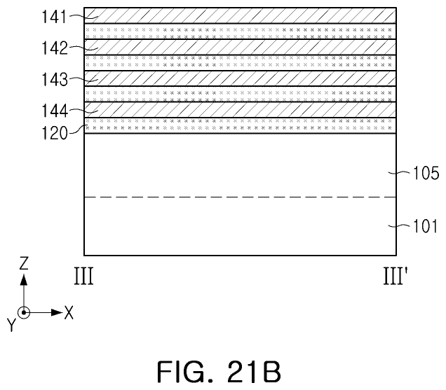

Referring to FIGS. 21A and 21B, the first etching mask 10 and the thickness adjustment layer 134 may be removed, and the isolation layer 110 may be partially removed.

After the first etching mask 10 and the thickness adjustment layer 134 are removed, the isolation layer 110 may be partially removed from an upper surface thereof, such that the active region 105 may protrude. In example embodiments, the isolation layer 110 may be partially removed such that an upper surface thereof is positioned on a level, lower than that of an upper surface of the active region 105.

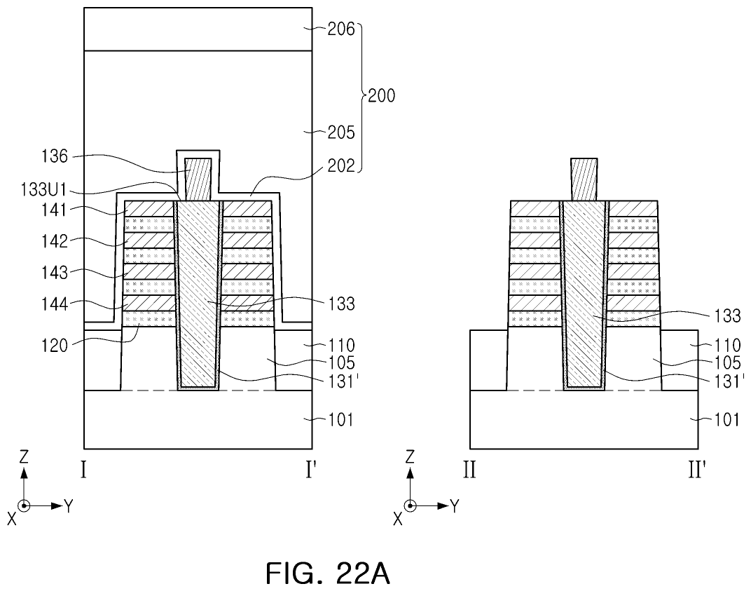

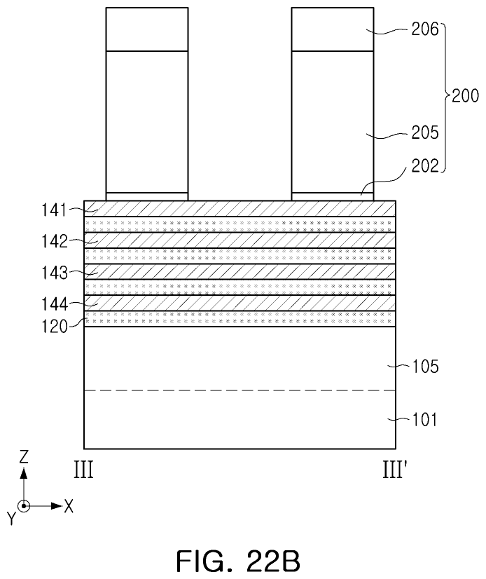

Referring to FIGS. 22A and 22B, sacrificial gate structures 200 may be formed on the active structure.

The sacrificial gate structure 200 may be a sacrificial structure formed in a region in which the gate dielectric layer 162 and the gate electrode 165 are disposed on the channel structures 140 through a subsequent process, as illustrated in FIGS. 3A and 3C. As illustrated in FIG. 3B, the sacrificial gate structure 200 may not be formed in a region in which the source/drain region 150 is to be formed. The sacrificial gate structure 200 may be in the form of a line, intersecting the active structure and extending in one direction. The sacrificial gate structures 200 may extend in the Y-direction, and may be disposed to be spaced apart from each other in the X-direction.

The sacrificial gate structure 200 may include first and second sacrificial gate layers 202 and 205 and a mask pattern layer 206, sequentially stacked. The first and second sacrificial gate layers 202 and 205 may be patterned using a mask pattern layer 206. The first and second sacrificial gate layers 202 and 205 may be an insulating layer and a conductive layer, respectively, but the present inventive concept is not limited thereto, and the first and second sacrificial gate layers 202 and 205 may be formed as a single layer. For example, the first sacrificial gate layer 202 may include silicon oxide, and the second sacrificial gate layer 205 may include polysilicon. The mask pattern layer 206 may include silicon oxide and/or silicon nitride.

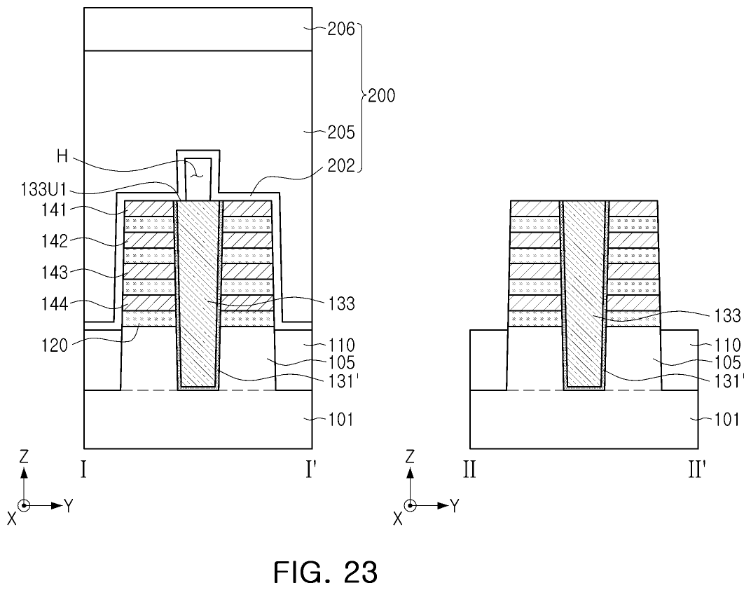

Referring to FIG. 23, the sacrificial wall 136 may be removed to form a dielectric wall hole H.

The sacrificial wall 136 may include a material included in the sacrificial layers 120 and the first, second, third, and fourth channel layers 141, 142, 143, and 144, and a material having an etch selectivity, and only the sacrificial wall 136 may be selectively removed without loss of the sacrificial layers 120 and the first, second, third, and fourth channel layers 141, 142, 143, and 144. The sacrificial wall 136 may be selectively removed from a lower portion of the sacrificial gate structure 200 to form the dielectric wall hole H. In example embodiments, the formation of the dielectric wall hole H may be performed using a wet etching process or an isotropic dry etching process.

According to the present inventive concept, the sacrificial wall 136 may include a material having an etch selectivity with respect to the channel structures 140, thereby preventing loss of the sacrificial layers 120 and the first, second, third, and fourth channel layers 141, 142, 143, and 144 from occurring or minimizing loss of the sacrificial layers 120 and the first, second, third, and fourth channel layers 141, 142, 143, and 144 in a process of removing the sacrificial wall 136. In particular, the first channel layer 141 may be partially prevented from being removed from an upper surface thereof. Accordingly, a semiconductor device may have improved reliability while including the first upper dielectric wall 135 for separation of the gate electrode 165.

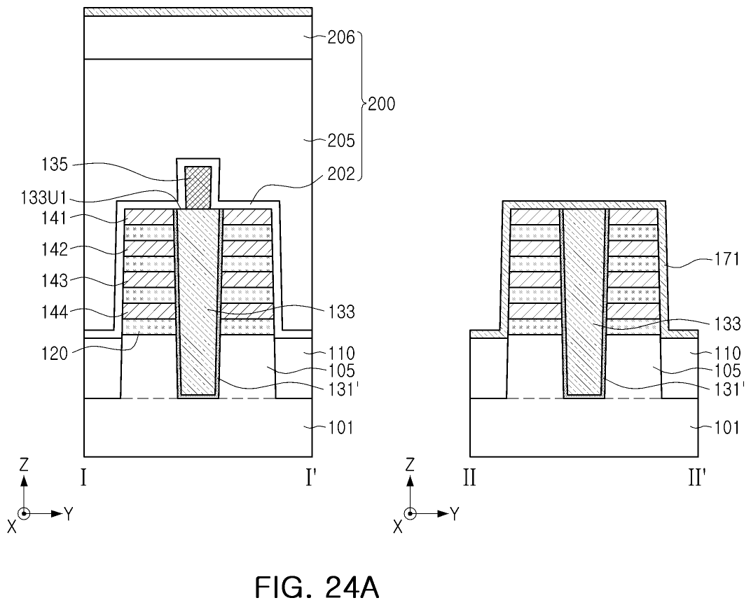

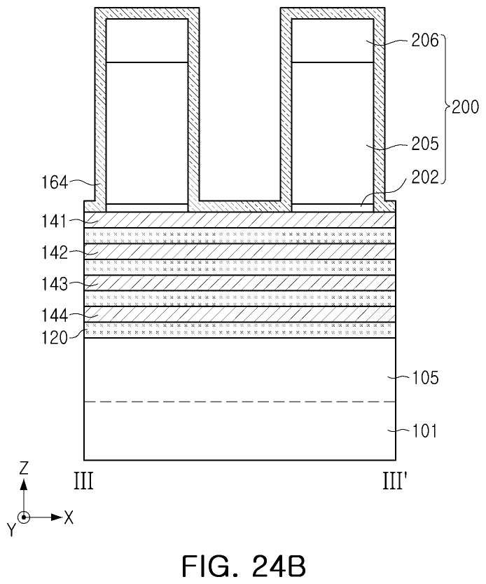

Referring to FIGS. 24A and 24B, the first upper dielectric wall 135 and a gate spacer layer 164 may be formed.

The first upper dielectric wall 135 may be formed to fill the dielectric wall hole H below the sacrificial gate structure 200, and the gate spacer layer 164 may be formed to conformally cover or overlap an upper surface of the first channel layer 141, and an upper surface and side surfaces of the sacrificial gate structure 200. In example embodiments, the first upper dielectric wall 135 and the gate spacer layer 164 may be formed using the same process. For example, as an insulating material for forming the gate spacer layer 164 is deposited, the insulating material may be deposited in the dielectric wall hole H to fill the dielectric wall hole H, and such a portion may form the first upper dielectric wall 135. The first upper dielectric wall 135 may be formed by forming a dielectric layer on an edge of the dielectric wall hole H, and filling a space of the dielectric wall hole H with a dielectric material. The gate spacer layer 164 may be formed using a plurality of insulating material deposition processes, and thus may include a plurality of insulating layers. The first upper dielectric wall 135 may also include a plurality of insulating layers formed using a plurality of deposition processes. In example embodiments, the first upper dielectric wall 135 and the gate spacer layer 164 may be formed of an insulating material having a dielectric constant, lower than that of the lower dielectric wall 133. However, in example embodiments, the first upper dielectric wall 135 may be formed using a process different from a process of forming the gate spacer layer 164. In a process of forming the first upper dielectric wall 135 and the gate spacer layer 164, a peripheral insulating layer 171 may be formed on the active structure exposed from the sacrificial gate structure 200. In the present operation, depending on a process, the first upper dielectric wall 135 may be in the form of various example embodiments such as FIGS. 4 to 12.

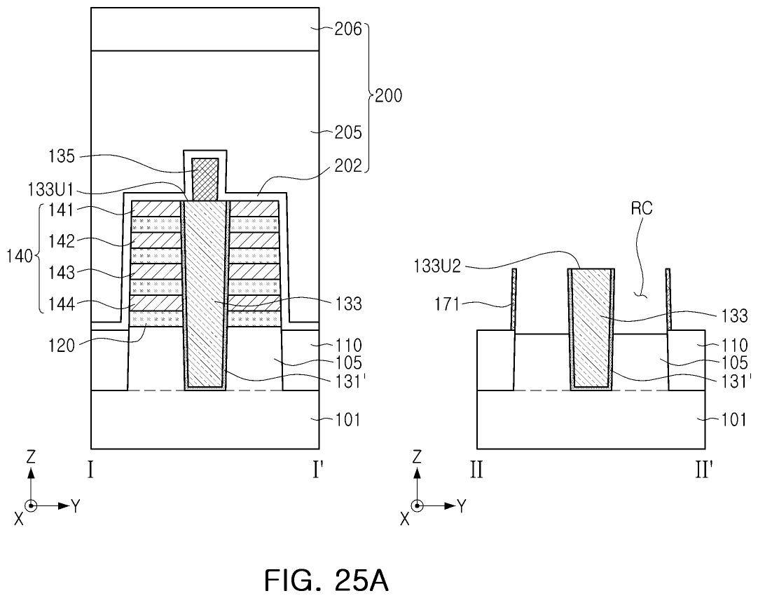

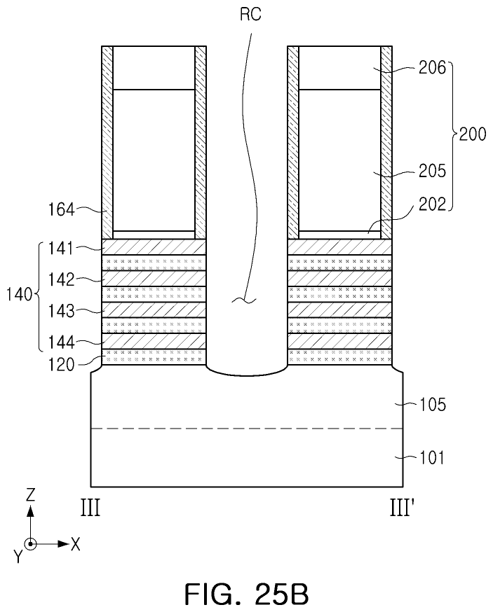

Referring to FIGS. 25A and 25B, recess regions RC may be formed by partially removing the sacrificial layers 120 and the first, second, third, and fourth channel layers 141, 142, 143, and 144 exposed from the sacrificial gate structures 200.

The recess regions RC may be formed by removing a portion of the exposed sacrificial layers 120 and a portion of the first, second, third, and fourth channel layers 141, 142, 143, and 144, using the sacrificial gate structures 200 and the gate spacer layers 164 as masks. Accordingly, the first, second, third, and fourth channel layers 141, 142, 143, and 144 may form the channel structures 140 having a limited length in the X-direction. A portion of the peripheral insulating layer 171 may be removed, and the other portion of the peripheral insulating layer 171 may remain. In example embodiments, unlike that illustrated, side surfaces of the sacrificial layers 120 may be selectively etched with respect to the channel structures 140 using a wet etching process, and thus the sacrificial layers 120 may be removed to a predetermined depth from side surfaces thereof in the X-direction. Accordingly, the sacrificial layers 120 may have inwardly concave side surfaces using side etching. A specific shape of the side surfaces of the sacrificial layers 120 is not limited to that illustrated in FIG. 25B.

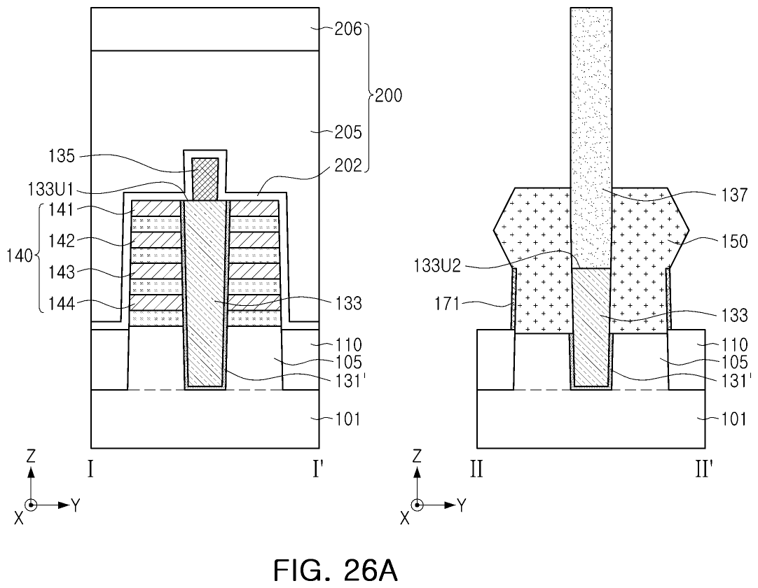

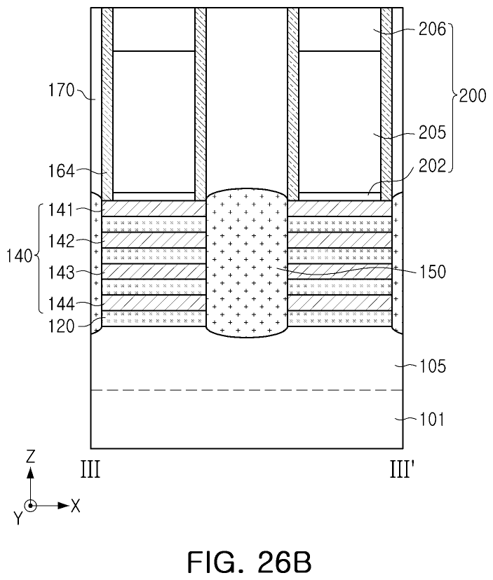

Referring to FIGS. 26A and 26B, a second upper dielectric wall 137 may be formed on the lower dielectric wall 133 exposed from the sacrificial gate structures 200, and source/drain regions 150 may be formed in the recess regions RC.

The second upper dielectric wall 137 may be formed by filling an insulating material in a region exposed from the sacrificial gate structure 200, forming a hole exposing a portion of the lower dielectric wall 133, and filling an insulating material to be included in the second upper dielectric wall 137. Before the source/drain regions 150 are formed, a portion of the cladding film 131′, covering or overlapping side surfaces of the lower dielectric wall 133 in the Y-direction, may be removed. After the insulating material, filled for the formation of the second upper dielectric wall 137, is removed, the source/drain regions 150 may be grown from an upper surface of the active region 105 and side surfaces of the channel structure 140 using a selective epitaxial process. The source/drain regions 150 may include a plurality of epitaxial layers. The epitaxial layers, included in the source/drain regions 150, may include impurities by in-situ doping, and may have different compositions and/or doping concentrations.

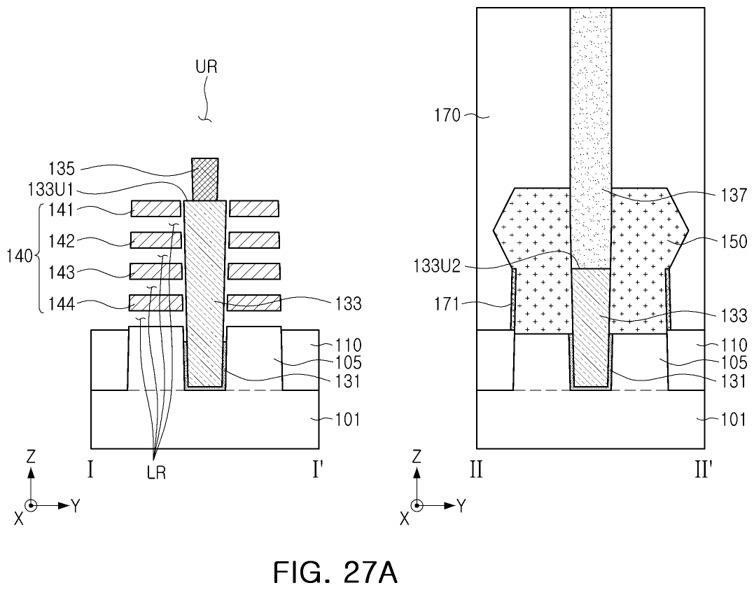

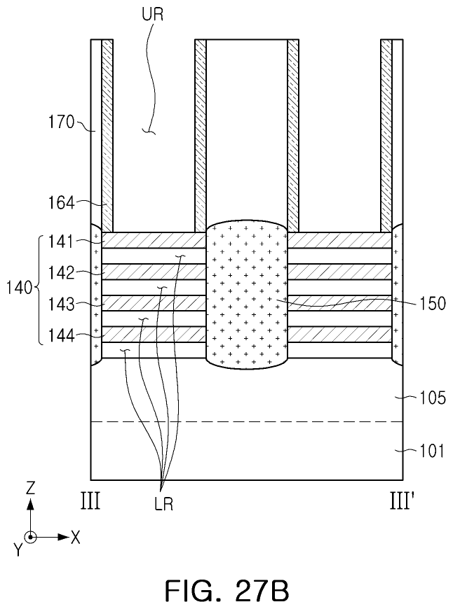

Referring to FIGS. 27A and 27B, an interlayer insulating layer 170 may be partially formed, and the sacrificial gate structures 200 and the sacrificial layers 120 may be removed.

The interlayer insulating layer 170 may be formed by forming an insulating film, covering or overlapping the sacrificial gate structures 200 and the source/drain regions 150, and performing a planarization process thereon.

The sacrificial gate structures 200 and the sacrificial layers 120 may be selectively removed with respect to the gate spacer layers 164, the interlayer insulating layer 170, and the channel structures 140. First, the sacrificial gate structures 200 may be removed to form upper gap regions UR, and then the sacrificial layers 120, exposed through the upper gap regions UR, may be removed to form lower gap regions LR. For example, when the sacrificial layers 120 include silicon germanium (SiGe) and the channel structures 140 include silicon (Si), the sacrificial layers 120 may be selectively removed with respect to the channel structures 140 and the source/drain regions 150 by performing a wet etching process. After the sacrificial layers 120 are removed, an exposed portion, among portions of the cladding film 131′ covering or overlapping side surfaces of the lower dielectric wall 133 in the Y-direction, may be removed to form the lower cladding film 131. In example embodiments, a process of partially removing the cladding film 131′ may be performed using an etching process using hydrogen fluoride (HF). In the present process, when a partial cladding film 131′ remains between the channel structures 140 and the lower dielectric wall 133, upper cladding films 132 according to the example embodiment of FIG. 15 may be formed.

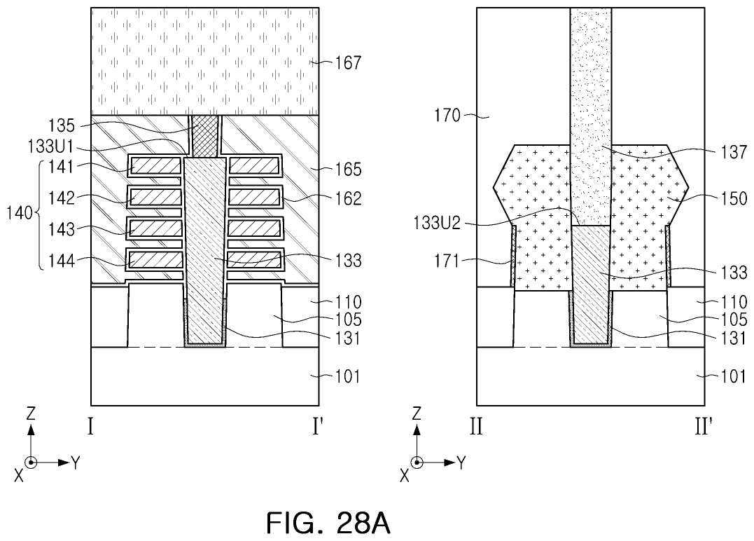

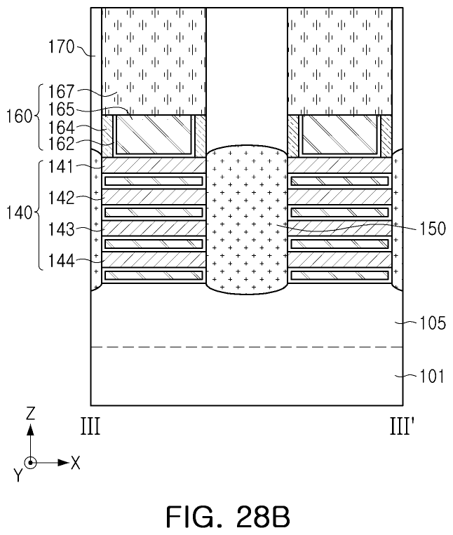

Referring to FIGS. 28A and 28B, gate dielectric layers 162, a gate electrode 165, and a gate capping layer 167 may be formed to form gate structures 160.

The gate dielectric layers 162 and the gate electrode 165 may be formed to fill the upper gap regions UR and the lower gap regions LR. The gate dielectric layers 162 may be formed to conformally cover or overlap internal surfaces of the upper gap regions UR and the lower gap regions LR. The gate electrode 165 may be formed to entirely fill the upper gap regions UR and the lower gap regions LR, and may then be removed to a predetermined depth from upper portions of the upper gap regions UR together with the gate dielectric layers 162 and the gate spacer layers 164. The gate capping layer 167 may be formed on the gate electrode 165 and the first upper dielectric wall 135 to extend in the first direction. Hereinafter, referring to FIGS. 3B and 3C together, a contact hole, passing through the interlayer insulating layer 170, may be formed by partially removing the source/drain regions 150 from upper portions thereof, and then the contact hole may be filled with a conductive material to form contact plugs 180. Accordingly, the semiconductor devices 100 of FIGS. 1 to 5 may be manufactured. Although not illustrated in detail, metal interconnections, electrically connected to the contact plugs 180, may be formed on the contact plugs 180.

In example embodiments, a semiconductor device, connected below the substrate 101 or forming a backside power delivery network (BSPDN) forming backside power structures formed by replacing the substrate 101 with an insulating layer, may be manufactured in a subsequent process.

According to example embodiments of the present inventive concept, a first upper dielectric wall, separating gate electrodes from each other, may be formed using a process different from that of a lower dielectric wall, thereby preventing loss of adjacent components that may occur during the process, and providing a semiconductor device having improved reliability.

While example embodiments have been shown and described above, it will be apparent to those skilled in the art that modifications and variations could be made without departing from the scope of the present inventive concept as defined by the appended claims.

What is claimed is:

1. A semiconductor device comprising:
a substrate;
a dielectric wall structure extending in a first direction on the substrate;
active regions extending in the first direction on sides of the dielectric wall structure;
a gate structure extending in a second direction perpendicular to the first direction on the substrate, intersecting the dielectric wall structure;
a plurality of channel layers on the active regions and spaced apart from each other in a third direction perpendicular to the first direction and the second direction, wherein the plurality of channel layers are at least partially surrounded by the gate structure; and
source/drain regions on at least one side of the gate structure, on the sides of the dielectric wall structure, wherein the source/drain regions are electrically connected to the plurality of channel layers,
wherein the dielectric wall structure comprises a lower dielectric wall extending in the first direction, and a first upper dielectric wall on the lower dielectric wall, and
wherein a first upper surface of the lower dielectric wall has a first width, and a lower surface of the first upper dielectric wall has a second width less than the first width.

2. The semiconductor device of claim 1, wherein the plurality of channel layers comprises a first channel layer, and
wherein the first upper surface of the lower dielectric wall is coplanar with or closer to the substrate than an upper surface of the first channel layer.

3. The semiconductor device of claim 2, wherein the plurality of channel layers further comprise a second channel layer below the first channel layer and a third channel layer below the second channel layer, and
wherein the first upper surface of the lower dielectric wall is further from the substrate than an upper surface of the third channel layer.

4. The semiconductor device of claim 2, wherein a distance in the third direction between the first upper surface of the lower dielectric wall and the upper surface of the first channel layer is 20 nm or less.

5. The semiconductor device of claim 2, wherein a distance in the second direction between the first upper surface of the lower dielectric wall and the first channel layer is 1 nm to 5 nm.

6. The semiconductor device of claim 1, wherein the gate structure comprises:
a gate electrode at least partially surrounding the plurality of channel layers;
gate dielectric layers respectively between the gate electrode and the plurality of channel layers, between the gate electrode and the dielectric wall structure, and between the gate electrode and one of the plurality of active regions; and
gate spacer layers on side surfaces of the gate electrode, wherein the gate spacer layers are on the plurality of channel layers, and
wherein the first upper dielectric wall comprises a material same as that of the gate spacer layers.

7. The semiconductor device of claim 1, wherein the dielectric wall structure further comprises a lower cladding film extending in the first direction between the lower dielectric wall and the active regions and between the lower dielectric wall and the substrate,
wherein the lower cladding film comprises a material different from that of the lower dielectric wall.

8. The semiconductor device of claim 1, wherein the dielectric wall structure further comprises an upper cladding film between at least one of the plurality of channel layers and the lower dielectric wall.

9. The semiconductor device of claim 1, wherein the first upper dielectric wall comprises a plurality of dielectric layers.

10. The semiconductor device of claim 1, wherein the dielectric wall structure comprises a second upper dielectric wall on the lower dielectric wall and partially overlapping the source/drain regions in the second direction,, and
wherein a second upper surface of the lower dielectric wall in contact with the second upper dielectric wall is closer to the substrate than the first upper surface.

11. The semiconductor device of claim 10, wherein the first upper dielectric wall and the second upper dielectric wall comprise a material different from that of the lower dielectric wall.

12. The semiconductor device of claim 10, wherein an upper surface of the second upper dielectric wall is further from the substrate than an upper surface of the first upper dielectric wall.

13. The semiconductor device of claim 10, wherein the second upper surface of the lower dielectric wall has a third width, and
wherein a fourth width of a lower surface of the second upper dielectric wall is less than the third width.

14. The semiconductor device of claim 1, wherein the first width is 10 nm to 25 nm, and
wherein the second width is 5 nm to 15 nm.

15. A semiconductor device comprising:
a substrate;
a dielectric wall structure extending in a first direction on the substrate;
a gate structure extending in a second direction perpendicular to the first direction on the substrate, intersecting the dielectric wall structure, the gate structure comprising gate electrodes separated from each other by the dielectric wall structure; and
a plurality of channel layers spaced apart from each other in a third direction perpendicular to the first direction and the second direction, wherein the plurality of channel layers are on sides of the dielectric wall structure, and the plurality of channel layers are respectively at least partially surrounded by the gate electrodes,
wherein, in a region in which the dielectric wall structure overlaps the gate electrodes in the second direction, a side surface of the dielectric wall structure has a step structure.

16. The semiconductor device of claim 15, wherein the step structure of the dielectric wall structure is closer to the substrate than upper surfaces of the gate electrodes.

17. The semiconductor device of claim 16, wherein the side surface of the dielectric wall structure is inclined to have a decreasing width toward the substrate, closer to the substrate than the step structure.

18. A semiconductor device comprising:
a substrate comprising an active region extending in a first direction;
a gate structure extending in a second direction perpendicular to the first direction on the substrate, intersecting the active region;
a dielectric wall structure extending in the first direction, the dielectric wall structure extending into the gate structure;
source/drain regions in regions in which the active region is recessed, on sides of the gate structure; and
a contact plug partially recessed into an upper surface of the source/drain region,
wherein the contact plug is electrically connected to the source/drain region, wherein the dielectric wall structure comprises a first upper dielectric wall overlapping the gate structure in the second direction, a second upper dielectric wall comprising a region overlapping the source/drain region in the second direction, and a lower dielectric wall extending in the first direction below the first upper dielectric wall and the second upper dielectric wall, and
wherein the first upper dielectric wall comprises a material having a dielectric constant, lower than that of the lower dielectric wall.

19. The semiconductor device of claim 18, wherein the first upper dielectric wall and the second upper dielectric wall comprise a material different from that of the lower dielectric wall.

20. The semiconductor device of claim 18. wherein the first upper dielectric wall comprises at least one of SIN, SiCN, and/or SiOCN.
